(19) United States
(12) Patent Application Publication
(10) Pub. No.: US 2002/0090464 A1
(43) Pub. Date: Jul. 11, 2002

(54) Sputter chamber shield

(76) Inventors: Mingwei Jiang, Sunnyvale, CA (US); Mikhail Shkolnikov, San Jose, CA (US)

Correspondence Address: Knobbe Martens Olson & Bear LLP, Intellectual Property Law, Sixteenth Floor, 620 Newport Center Drive, Newport Beach, CA, 92660, US

(21) Appl. No.: 09/989,508

(22) Filed: Nov. 20, 2001

Related U.S. Application Data
(60) Provisional application No. 60/250,529, filed on Nov. 28, 2000.

(51) Int. Cl. C25B 9/00; C25B 11/00; C25B 13/00; C23C 14/00; C23C 4/00; C23C 16/00

(52) U.S. Cl. 427/446; 118/733; 118/723 R; 204/298.11

(57) ABSTRACT

Particulate contamination can occur in physical vapor deposition (PVD) systems when sputtered target material accumulates on the walls of the processing chamber and flakes off onto the workpiece. In a method for preparing a shield to reduce particulate contamination, sheet metal is formed to conform to the surfaces of the deposition chamber. The base metal is roughened, such as by sand blasting. A layer of coating material, whose coefficient of thermal expansion (CTE) is similar to that of the target material, is applied to the roughened base metal surface by a thermal spraying process. The surface of the coating is very rough, more than five times rougher than the underlying base metal texture. When the coating CTE and surface roughness are chosen carefully, shield performance can be optimized, resulting in longer processing times between shield replacements, reduced PVD chamber maintenance and less down time in these systems.

### REFERENCE TO RELATED APPLICATION

This application claims the priority benefit under 35 U.S.C. § 119(e) from provisional application No. 60/250,529, filed Nov. 28, 2000, entitled SPUTTER CHAMBER SHIELD.

### FIELD OF THE INVENTION

This invention relates generally to shields for physical vapor deposition chambers and methods for producing the same, and, more particularly, to shields for ZnS—SiO₂ deposition chambers for compact disc manufacturing.

### BACKGROUND OF THE INVENTION

Shielding techniques have been used in physical vapor deposition processing for many years to prevent sputtered material from coating the inside surface of the process chamber. Instead, sputtered material coats the shield which can be removed and replaced when the layer reaches a thickness such that particles begin to flake off and contaminate the process chamber. Particles in the chamber may be incorporated into the growing film on the workpiece, producing defects and decreasing yields. Accordingly, when the shield is coated to the point at which flaking can occur, the process chamber is shut off, and the shield is cleaned or replaced. Some systems employ a periodic clean or etch cycle to extend the number of deposition cycles between shield replacements.

Typical shields are made from aluminum or stainless steel sheet metal formed to cover the interior surfaces of the process chamber. Manufacturers often use sandblasting to roughen the shield, which allows them to run the sputtering chamber for longer periods of time without a shield change, reducing the down time of the process equipment. Reduced down time translates directly to manufacturing cost savings.

Accordingly, a need exists for shields that last even longer than those currently employed, such that manufacturers can reduce maintenance time and increase operating time on their physical vapor deposition equipment.

### SUMMARY OF THE INVENTION

In accordance with one aspect of the invention, a method is provided for preparing a shield to use in a zinc sulfide/silicon dioxide deposition process chamber. The method includes providing a baseplate configured to cover an interior surface of the process chamber. This baseplate is then roughened. A coating is provided over the baseplate with both a greater surface roughness and a greater adhesion strength as compared to the roughened baseplate.

In accordance with another aspect of the invention, a shield is provided for a deposition chamber, which is configured for depositing layers on a compact disc substrate. The shield includes a baseplate with a surface roughness between about 60 μinch Ra and 250 μinch Ra. A coating is formed directly over the baseplate and has a surface roughness that is greater than about 600 μinch Ra.

In accordance with another aspect of the invention, a sputtering reactor is provided for producing compact discs. The reactor includes a process chamber defined by walls and a zinc sulfur/silicone dioxide sputtering target. A shield, covering at least some surfaces of the process chamber walls, includes a coating with a surface roughness greater than about 800 μinch Ra. The coating has a coefficient of thermal expansion between about 1×10⁻⁶ inch/F. and 15×10⁻⁶ inch/F.

### BRIEF DESCRIPTION OF THE DRAWINGS

These and other aspects of the invention will be readily apparent from the detailed description below and from the appended drawings, which are meant to illustrate and not to limit the invention, and in which:

FIG. 1 is a cross-sectional view of a physical vapor deposition chamber, including a three-piece sputter shield constructed in accordance with a preferred embodiment of the present invention.

FIG. 2A is a top plan view of a top section of the shield of FIG. 1.

FIG. 2B is a cross-section view taken along lines 2B-2B of FIG. 2A.

FIG. 2C is an enlarged cross-section view of the top section of the shield in FIG. 2B.

FIG. 3A is a top plan view of a middle section of the shield of FIG. 1.

FIG. 3B is a cross-section view taken along lines 3B-3B of FIG. 3A.

FIG. 3C is an enlarged cross-section view of the middle section of the shield in FIG. 3B.

FIG. 4A is a top plan view of a lower section of the shield of FIG. 1.

FIG. 4B is a cross-section view taken along lines 4B-4B of FIG. 4A.

FIG. 4C is an enlarged cross-section view of the lower piece of the shield in FIG. 4B.

FIG. 5 is a process flow diagram generally illustrating a method of preparing the shield for a physical vapor deposition chamber, in accordance with a preferred embodiment of the present invention.

FIG. 6 is an enlarged cross-section diagram of a grit-blasted base metal sheet, over which a rough metal layer has been deposited in accordance with the preferred embodiment.

### DETAILED DESCRIPTION OF THE PREFERRED EMBODIMENT

One process used in the production of read/write compact discs (CD-RW) is physical vapor deposition of ZnS—SiO₂ (zinc sulfide with a silicon dioxide binder material), which is a material much like a ceramic, onto a substrate. Inevitably, the physical vapor deposition process (sputtering) results in material being deposited onto the chamber walls. Because ZnS—SiO₂ is very brittle, the film that is deposited is especially prone to flaking and shedding from the walls, contaminating the process environment. Currently CD-RW producers use shields made from aluminum or stainless steel that have sand-blasted texture only.

In CD-RW processing, the ZnS—SiO₂ deposition step is a major source of contamination that results in a loss of yield to the CD-RW manufacturer. Typically, it is necessary to replace shields that cover the walls as frequently as every 12 hours and to clean the chamber of dust every four hours. It is desirable, therefore, to seek ways to reduce flaking and, thereby, to lengthen the time between shield replacements and to reduce the frequency of chamber maintenance.

Thus, particulate contamination can occur in physical vapor deposition (PVD) systems when sputtered target material accumulates on the walls of the processing chamber and flakes off. The object of the preferred embodiments is to reduce particulate generation in PVD processing machines wherein ZnS—SiO₂ is deposited onto CD-RW discs. This is achieved by shielding the inside of the deposition chamber and addressing issues of: 1) differential thermal expansion between deposited ZnS—SiO₂ material and the shield material, and 2) mechanical adhesion of the ZnS—SiO₂ accumulated layer to the shield. Materials with coefficients of thermal expansion similar to ZnS—SiO₂ are chosen for coating the sheet metal shield. These are applied using a thermal spraying process, such as thermal arc, flame or plasma spraying. These processes deposit very rough coatings (up to 1200 μinch) which enhance the adhesion of ZnS—SiO₂ to the shield by enlarging the contact area and breaking the continuity of the ZnS—SiO₂ films. An additional benefit is that, after the shield is removed from the chamber during regular maintenance, the ZnS—SiO₂ and coating layers can be stripped from the sheet metal, and the shield can be reprocessed by applying new thermal spray coatings. In this way a shield can be recycled many times. It has been found that a shield prepared according to the preferred embodiment can be used without flaking for as much as three to four times longer than shields roughened by grit-blasting alone.

Two major mechanisms are responsible for particle shedding: 1) poor mechanical adhesion of the physical vapor deposition layer to the shield surface; and 2) differential thermal expansion between the physical vapor deposition layer and the underlying base metal. Once particles are shed off into the chamber, they can become incorporated into the growing film on the workpiece, producing defects and decreasing yields.

Sand blasting of sheet metal shields produces a surface texture that provides some degree of mechanical adhesion for layers deposited thereover. The inventors have found, however, that greater roughness entails even better adhesion, particularly for sputtered ZnS—SiO₂ films. The preferred embodiments employ metal deposition techniques whereby an additional metal layer is deposited onto prepared sheet metal shields. That additional metal layer has a very rough surface and high adhesion strength to the base metal. In particular, thermal arc spraying, flame spraying or plasma spraying can produce metal coatings with roughness measurements nearly five times rougher than can be achieved with sand blasting alone.

At the same time, the addition of a rough coating affords the opportunity to match thermal expansion properties of the shield and the sputtered material. Stress between the physical vapor deposition overlayer and the underlying shield occurs when the two materials have very different coefficients of thermal expansion and, therefore, expand at different rates as the temperature in the chamber changes. As each workpiece is introduced into the chamber, processed and removed, the process chamber undergoes thermal cycling. These repeated temperature changes result in delamination or flaking of the physical vapor deposition overlayer from the underlying shield, and particulate shedding can occur.

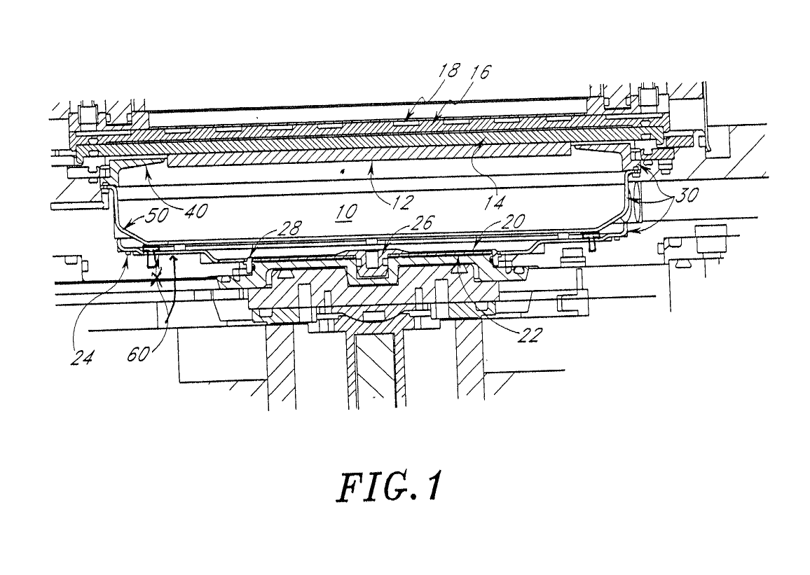

FIGS. 1, 2, 3 and 4 represent a starting point for the preferred embodiments of the present invention. Though illustrated in the context of a sputtering chamber for CD-RW manufacturing, the skilled artisan will readily find application for the principles disclosed herein to other deposition systems. The invention has particular utility, though, for shielding ZnS—SiO₂ PVD chambers.

FIG. 1 is a detailed diagram of a physical vapor deposition system viewed in cross section, which includes shielding of the type described in the preferred embodiment. A deposition chamber 10 contains, along its ceiling, a sputtering target 12 attached to a backing plate 14. The chamber 10 and its surrounding components are described in more detail in pending of Lee et al., having U.S. Patent application Ser. No. 09/547,986, filed on Apr. 12, 2000 and entitled HORIZONTAL SPUTTERING SYSTEM, the disclosure of which is incorporated herein by reference. The target 12 and backing plate 14 together define a cathode. The backing plate 14 is in direct contact with a cooling plate 16 through which water flows in grooves 18. A workpiece 20 is shown along the floor of the chamber where it is supported on a transport tray 22. A shield 30, covering chamber surfaces other than the target 12 and workpiece 20, is shown in three sections 40, 50, 60. In the illustrated embodiment, the thickness of the sheet metal varies from about 0.040 inch to 0.250 inch.

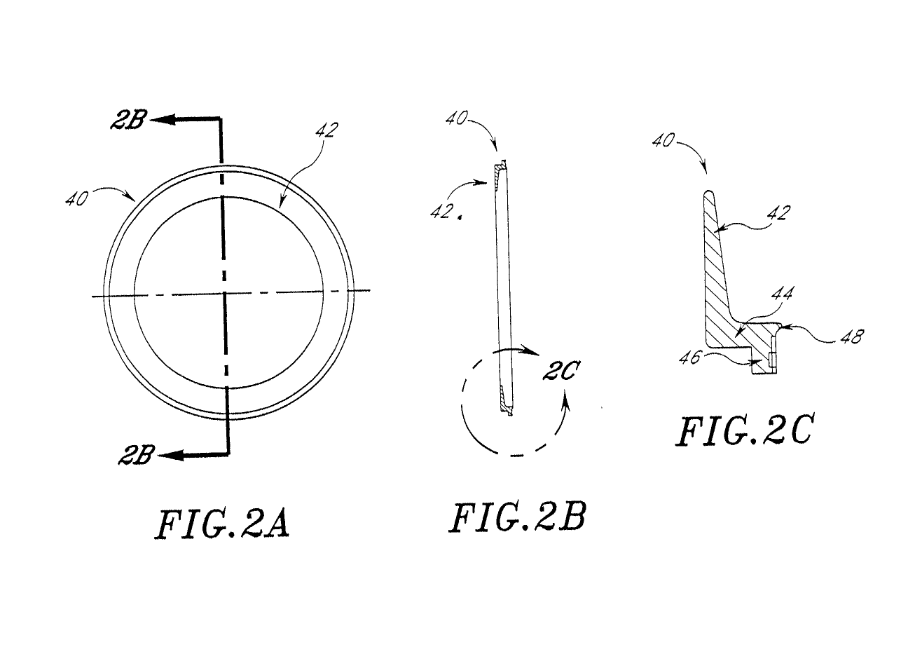

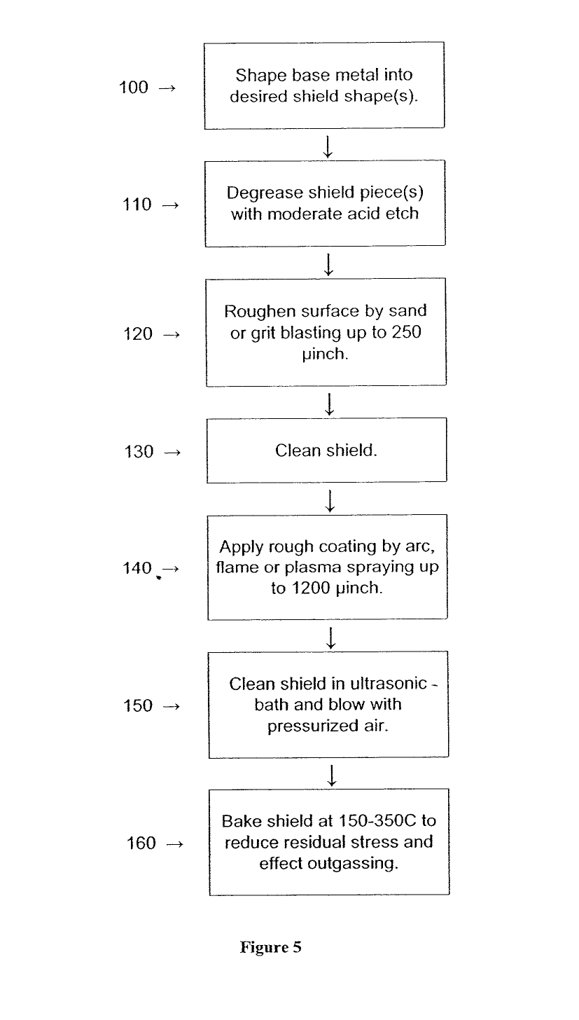

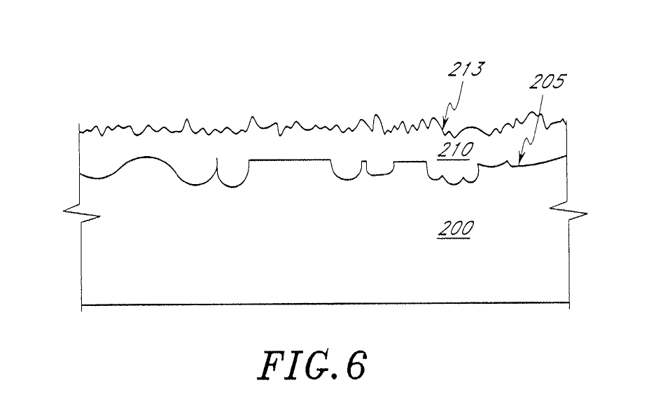

Referring to FIGS. 2A to 2C, the annular top shield section 40 is configured to fit along the ceiling of the chamber 10 around the target 12 (See FIG. 1). The top shield section 40 comprises a tapered upper segment 42, a depending sidewall segment 44 and a flange segment 46 extending from the sidewall segment 44. The upper segment 42 is in contact with the chamber ceiling with the thickest part at the outer edge of the chamber and rounded at the edge and close to the target 12. As best seen in FIG. 2C, the flat upper surface of the upper segment 42 of the annulus and the flat outer surface of the side wall segment 44 are configured to fit snugly against the ceiling and upper side wall at the comer of the deposition chamber 10. The flange segment 46 extends outwardly around the outside edge of the top shield 40, such that a top portion of middle shield section 50 can be bolted to it, as described below. A small, raised annular bead 48 extends around the innermost edge of the flange 46. Preferably, the inner surfaces of the top shield 40, facing the chamber, undergo the two step surface treatment, described in more detail with respect to FIGS. 5 and 6.

The middle shield section 50 is shown in FIG. 1 fitting against and along the sidewall of chamber 10 and bolted into place against the flange segment 46 of top shield section 40. Accordingly, the middle shield section 50 is shaped to conform closely to the sidewall of chamber 10.

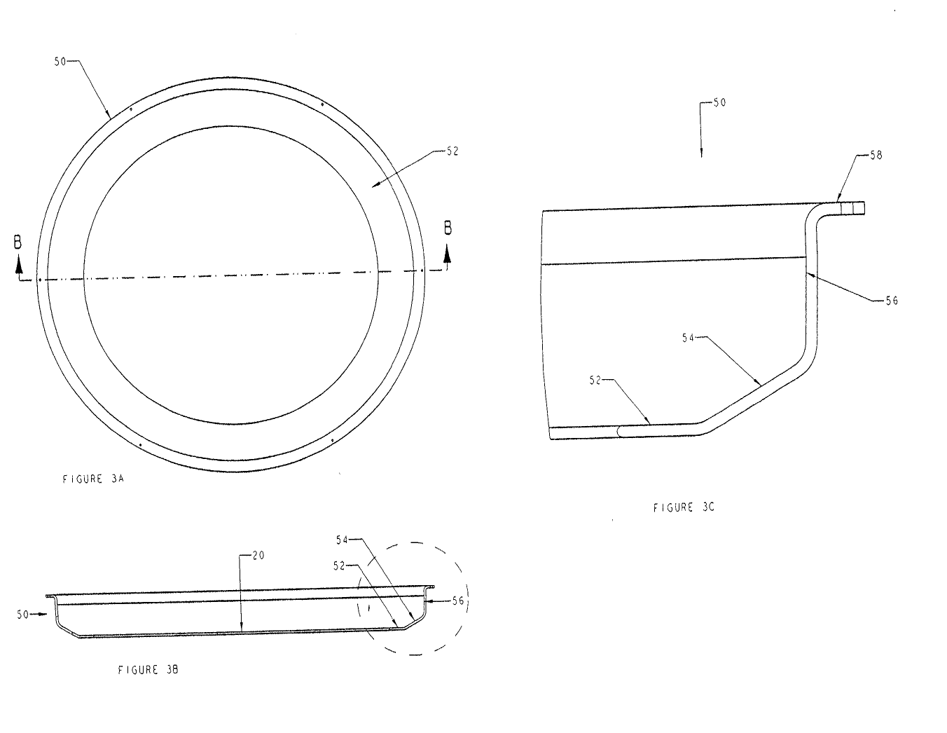

Referring to FIGS. 3A to 3C, the middle shield section 50 has a flat lower segment 52, the innermost edge of which is rounded. The lower segment 52 extends into an angled transition region 54 to conform to a beveled lower comer of the chamber wall. This angled segment 54 extends upwardly into a sidewall segment 56 and then outwardly into a flange segment 58. The flange segment 58 extends around the outside edge of middle shield section 50 and, as noted above, bolts onto the bottom portion of top shield segment 40.

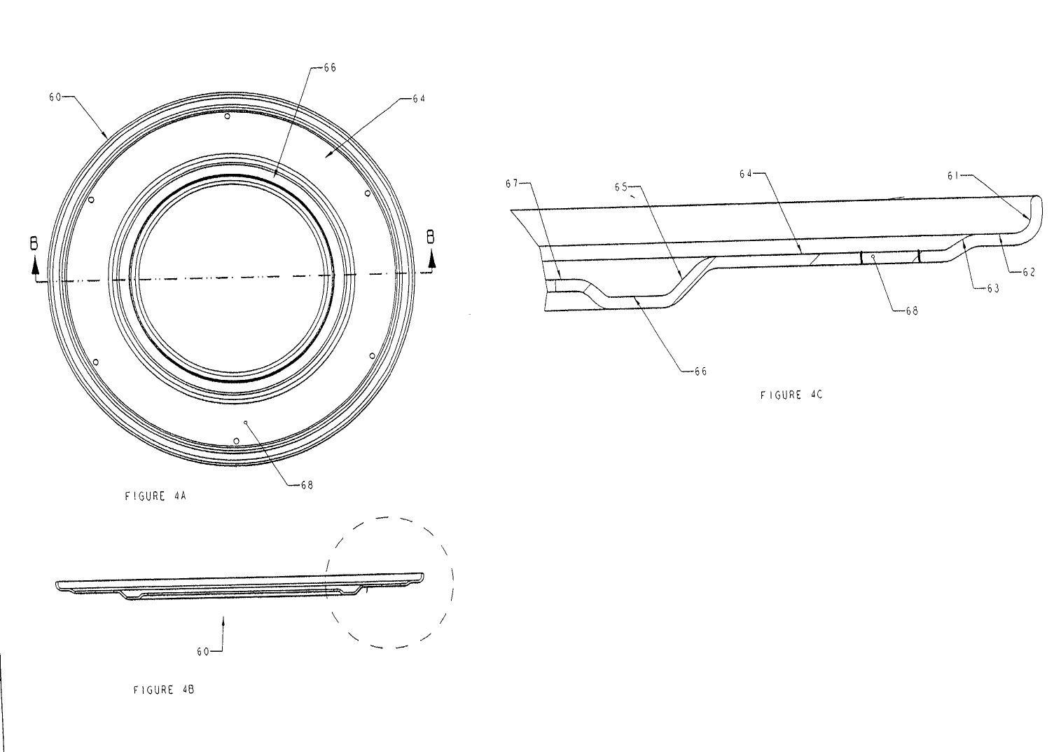

With reference now to FIGS. 4A to 4C, the bottom shield section 60 is also an annular piece including various segments shaped and sized to cover surfaces of the sputtering chamber. In particular, the bottom shield section 60 includes a short sidewall segment 61, smoothly transitioned into a horizontal platform 62, an angled transition region 63, a major horizontal intermediate segment 64, another angled segment 65, an inner platform 66 and an annular lip 67, from outer to inner edge of the annulus. As shown in FIG. 1, outer mask 28 fits over annular lip 67 and covers the outer edge of workpiece 20. The intermediate segment 64 includes bolt holes 68 for securing the bottom shield to the chamber floor.

Referring again to FIG. 1, the bottom shield section 60 is configured with its outer portion lying below a major part of middle shield section 50 and covering portions of the chamber floor not covered by the workpiece 20. Thermal contact between the bottom shield section 60 and the floor of the chamber is ensured by a contact spring (not shown) in annular groove 24.

In the illustrated embodiment, the workpiece 20 is held onto the transport tray 22 by an inner mask 26 and an outer mask 28. The transport tray 22 is part of a carousel that vertically translates during loading and unloading of the workpiece 20 and rotates in the lower position to bring the workpiece 20 in line with an adjacent chamber for sequential processing. The illustrated tool includes eight such chambers above the carousel, sufficient to conduct all the processes needed to convert a plastic substrate to a CD-RW. The skilled artisan will readily appreciate that, in other processing chambers, loading and unloading of the substrate 20 can be accomplished in any of a number of suitable ways.

It should be understood that the three-piece shield 30 arrangement, and the shapes of the individual sections 40, 50, 60 described above, represent one of many possible configurations that the skilled artisan might adapt for the physical vapor deposition chamber shown in FIG. 1 or for any other deposition system. Although the shield 30 described above covers nearly the entire inner surface of the chamber 10, other configurations that comprise a different number of sections and/or provide only partial coverage of the chamber surface are possible. Preferably, however, the shield 30 is configured to cover all inner surfaces of the chamber 10, with the exception of the sputtering target 12 and the workpiece 20.

With reference now to FIG. 5, a method for producing shields for physical vapor deposition systems is shown in accordance with the preferred embodiment. Initially, a baseplate material is shaped 100 to fit inside the physical vapor deposition chamber 10. The baseplate preferably has an initial thickness between about 0.020 inch and 0.500 inch, more preferably between about 0.040 inch and 0.250 inch (1 mm to 6.35 mm). Shaping 100 in the illustrated embodiment comprises compressing sheet metal between platens of an appropriate configuration to achieve the desired shape. In other arrangements, the skilled artisan will readily appreciate that a base metal can be shaped by molding, forging, etc. The base metal may comprise any suitable metal, but preferably comprises aluminum, as aluminum is lightweight, is suitably resistant to corrosion and is relatively inexpensive and readily available.

Shaping 100 is followed in the illustrated embodiment by degreasing 110 with a moderate acid etch to prepare the shield pieces for roughening 120, which is preferably accomplished by physical means, such as grit-blasting, sand-blasting or bead-blasting. These roughening techniques typically leave an initial surface texture with a roughness less than about 200 roughness average in micro-inches (μinch Ra, or simply μinch Ra), more particularly between about 60 μinch Ra and 250 μinch Ra. Sand blasting in the illustrated embodiment leaves a surface roughness between about 80 μinch Ra and 115 μinch Ra.

The next step in producing the shield is a cleaning step 130 in preparation for introducing a greater surface roughness to the already-textured shield. In the illustrated embodiment, this greater surface roughness is effected by depositing 140 coating, preferably by means of a thermal spraying process, such as thermal arc spraying, flame spraying or plasma spraying. An exemplary thermal arc spraying process is provided in U.S. Pat. No. 3,632,952, the disclosure of which is hereby incorporated herein by reference. Advantageously, these thermal spraying processes produce an even greater surface roughness for the shield. In particular, the resulting coating layer has a surface roughness typically in the range of400 μinch Ra to 1200 μinch Ra. Preferably the deposited layer has a roughness greater than about 600 μinch Ra, more preferably greater than about 800 μinch Ra, and in the preferred embodiment has a roughness between about 900 μinch Ra and 1000 μinch Ra. The layer is preferably deposited to a thickness between about 0.005 inch and 0.020 inch, more preferably between about 0.006 inch and 0.012 inch.

Applying a rough coating 140 preferably includes first selecting a coating material to closely match the coefficient of thermal expansion (CTE) of the target material 12 (FIG. 1). In the illustrated embodiment, where a zinc sulfide material with a silicon dioxide binder material (ZnS—SiO₂) is deposited as part of a process for making read/write compact discs (CD-RW), the CTE of the target material is about 5.4×10⁻⁶ inch/F. In particular, the CTE of the deposited coating is preferably between about 1×10⁻⁶ inch/F. and 15×10⁻⁶ inch/F., more preferably between about 2×10⁻⁶ inch/F. and 7.5×10⁻⁶ inch/F. Suitable coating materials, therefore, include aluminum (13.3×10⁻⁶ inch/F.) and, more preferably, molybdenum (3.0×10⁻⁶ inch/F.), nickel (7.4×10⁻⁶ inch/F.) chromium (3.4×10⁻⁶ inch/F.) and titanium (4.7×10⁻⁶ inch/F). Suitable deposition processes are known for each of these materials. The skilled artisan can readily select alternative materials with appropriate CTEs for matching ZnS—Si0₂ or other deposited materials.

After deposition, the shield is cleaned 150 in an ultrasonic bath and blasted with pressurized air. The shield is then baked 160 at 150C. -350C. to relieve stress and allow outgassing from the finished product.

FIG. 6 is a schematic drawing of a cross section of the shield material, preferably comprising a stainless steel or aluminum baseplate 200, after it has undergone the two surface treatment steps described in the preferred embodiment. The illustrated sheet metal baseplate 200 comprises aluminum with a roughened surface 205, having a surface roughness between about 80 μinch Ra and 115 μinch Ra as a result of the sandblasting step. A subsequent metal coating layer 210, formed over the baseplate 200 by a thermal spraying process, has a thickness preferably between about 0.005 inch and 0.020 inch, more preferably between about 0.006 inch and 0.012 inch. As noted above, the coating 210 is desirably selected from materials with coefficients of thermal expansion between about 1×10⁻⁶ inch/F. and 15×10⁻⁶ inch/F., including metals such as aluminum and, more preferably, between about 2×10⁻⁶ inch//F. and 7.5 ×10⁻⁶ inch/F., including metals such as molybdenum, chromium or titanium. The coating 210 has a surface 213 with a roughness greater than about 600 μinch Ra, preferably greater than 800 μinch Ra and, most preferably between about 900 μinch Ra and 1000 μinch Ra.

In one embodiment, an additional film of chromium is formed over the thermal sprayed coating, preferably by electrodepositing. Advantageously, chromium demonstrates good adhesion to ZnS—SiO₂, and also to underlying molybdenum or titanium. Electroplating gives good conformality, essentially transforming the roughness of the underlying surface to the chromium. Alternatively, chromium can be directly electrodeposited onto the impacted baseplate.

Advantageously, the surface roughness of the base metal 200 results in good adhesion for the overlying coating 210. Furthermore, an even greater surface roughness of the coating 210 results in tenacious adherence of deposited species onto the shield. Furthermore, the material of the coating 210 is carefully selected to match CTE with the deposited species, particularly ZnS—SiO₂. As the skilled artisan will appreciate in view of the present disclosure, matching CTE is of particular importance where the coating surface 213 has high roughness. Differential expansion of the shield coating 210 and the sputtered ZnS—SiO₂ becomes important especially where the sputtered layer on the shield extends into the microscopic crevices of the highly textured coating surface 215.

Although described above in connection with particular embodiments of the present invention, it should be understood that the descriptions of the embodiments are illustrative of the invention and are not intended to be limiting. Preferably, the above-described process is applied also to other exposed components, such as the outer surfaces of mask components 26 and 28. Various modifications and applications may occur to those skilled in the art without departing from the true spirit and scope of the invention, as defined in the appended claims.

We claim:

1. A method of preparing a shield to use in a ZnS—SiO₂ deposition process chamber, comprising:
providing a baseplate configured to cover an interior surface of the process chamber;
roughening the baseplate; and
providing a coating over the baseplate and a greater surface roughness and adhesion strength than the roughened baseplate.

2. The method according to claim 1, wherein the coating has a coefficient of thermal expansion between about 1×10⁻⁶ inch/F. and 15×10⁻⁶ inch/F.

3. The method according to claim 2, wherein the coating has a coefficient of thermal expansion between about 2×10⁻⁶ inch/F. and 7.5×10⁻⁶ inch/F.

4. The method according to claim 1, wherein providing the coating comprises a thermal spraying process.

5. The method according to claim 4, wherein providing the coating uses a method chosen from a group consisting of thermal arc spraying, flame spraying, and plasma spraying.

6. The method according to claim 1, wherein the coating is selected from the group consisting of molybdenum, titanium, nickel and aluminum.

7. The method according to claim 1, wherein the coating has a surface roughness greater than about 600 μinch Ra.

8. The method according to claim 7, wherein the coating has a surface roughness greater than about 800 μinch Ra.

9. The method according to claim 8, wherein the coating has a surface roughness between about 900 μinch Ra and 1000 μinch Ra.

10. The method according to claim 1, wherein roughening the baseplate produces a surface roughness of less than about 200 μinch Ra.

11. The method according to claim 10, wherein roughening the baseplate produces a surface roughness between about 80 μinch Ra and 115 μinch Ra.

12. The method according to claim 1, wherein roughening the baseplate comprises impacting and providing the coating comprises a thermal spraying process.

13. A shield for a deposition chamber configured for depositing layers on a compact disc substrate, comprising:
a baseplate having a surface roughness between about 60 μinch Ra and 250 μinch Ra; and
a coating directly over the baseplate having a surface roughness greater than about 600 μinch Ra.

14. The shield of claim 13, wherein the coating has a surface roughness greater than about 800 μinch Ra.

15. The shield of claim 14, wherein the coating has a surface roughness between about 900 μinch Ra and 1000 μinch Ra.

16. The shield of claim 13, wherein the baseplate comprises a material selected from the group consisting of aluminum and stainless steel.

17. The shield of claim 13, wherein the coating is selected from the group consisting of aluminum, molybdenum, chromium and titanium.

18. The shield of claim 13, wherein the coating has a coefficient of thermal expansion between about 1×10⁻⁶ inch/F. and 15×10⁻⁶ inch/F.

19. The shield of claim 18, wherein the coating has a coefficient of thermal expansion between about 2×10⁻⁶ inch/F. and 7.5×10⁻⁶ inch/F.

20. The shield of claim 13, wherein the baseplate has a thickness between about 0.020 inch and 0.500 inch

21. The shield of claim 13, wherein the baseplate has a thickness between about 0.040 inch and 0.250 inch.

22. The shield of claim 13, wherein the coating has a thickness between about 0.005 inch and 0.020 inch.

23. The shield of claim 22, wherein the coating has a thickness between about 0.006 inch and 0.012 inch.

24. A sputtering reactor for producing compact discs, comprising:
a process chamber defined by a plurality of walls and a ZnS—SiO₂ sputtering target; and
a shield including a coating with a surface roughness greater than about 800 μinch Ra covering at least some surfaces of the process chamber walls, the coating having a coefficient of thermal expansion between about 2×10−6 inch/F. and 7.5×10⁻⁶ inch/F.

25. The sputtering reactor of claim 24, wherein the shield comprises three sections.

26. The sputtering reactor of claim 24, wherein the shield comprises a baseplate under the coating, the baseplate having a grit-blasted surface.

27. The sputtering reactor of claim 26, wherein the baseplate has a sand-blasted surface.
